(19) United States
(12) Patent Application Publication
(10) Pub. No.: US 2021/0408403 A1
(43) Pub. Date: Dec. 30, 2021

(54) FLEXIBLE SUBSTRATE MATERIAL, METHOD OF MANUFACTURING FLEXIBLE DISPLAY PANEL SUBSTRATE AND FLEXIBLE DISPLAY PANEL

(71) Applicant: TCL CHINA STAR OPTOELECTRONICS TECHNOLOGY CO., LTD., Shenzhen (CN)

(72) Inventor: Zhiming XU, Shenzhen (CN)

(73) Assignee: TCL CHINA STAR OPTOELECTRONICS TECHNOLOGYCO., LTD., Shenzhen (CN)

(21) Appl. No.: 16/621,258

(22) PCT Filed: Nov. 13, 2019
(86) PCT No.: PCT/CN2019/117778

§ 371 Date: Dec. 11, 2019

(30) Foreign Application Priority Data
Jul. 24, 2019 (CN) 201910670910.3

(51) Int. Cl. H01L 51/00; H01L 51/56

(52) U.S. Cl. CPC H01L 51/0097; H01L 2251/5338; H01L 51/0048; H01L 51/56

(57) ABSTRACT

The present disclosure provides a flexible substrate material, a method of manufacturing a flexible display panel substrate and a flexible display panel. The flexible substrate material includes a polyimide substrate and a carbon nanotube reinforcement mixed in the polyimide substrate. The method of manufacturing a flexible display substrate provided by the present disclosure provides the flexible display panel substrate with better abilities of curl deformation resistance and crack resistance by introducing the carbon nanotube reinforcement phase into the synthesis process of the phase of the polyimide substrate. The flexible display panel substrate provided by the present disclosure has more excellent quality due to the flexible substrate with the abilities of curl deformation resistance and crack resistance.

### BACKGROUND OF INVENTION

### Field of Invention

The present invention relates to a field of flexible display technology, and more particularly, to a flexible substrate material, a method of manufacturing a flexible display panel substrate and the flexible display panel.

### Description of Prior Art

In recent years, flexible display panels are gradually gaining favor from the market. Major developers intensify the development and promotion of the manufacturing technologies of flexible display panel. Both of two main display panels currently on the market, crystal display panels and organic light emitting diode display panels, can achieve flexible display. Among them, the crystal display panel includes an array substrate and a color film substrate disposed opposite to the array substrate. Current technology uses flexible polyimide as a substrate of the array substrate and the color film substrate. During the manufacturing process, the flexible polyimide needs to be coated on a glass substrate, and then disposing other elements on the polyimide layer, followed by detaching the polyimide substrate from the glass substrate by laser stripping method. The manufacturing process of the organic light emitting diode display panel is similar to the manufacturing process of the crystal display panel. The manufacturing process of the organic light emitting diode display panel also uses polyimide as the flexible substrate material, and the polyimide substrate needs to be detached from the glass substrate in the last step.

Mechanical or thermal effects, such as laser stripping, are needed to detach the polyimide substrate from the glass substrate. However, the polyimide material used in the present technology has worse abilities of deformation resistance and crack resistance. Problems of curl deformation and crack of the polyimide substrate often occurs after detaching, and quality and yield of the products are seriously affected.

Accordingly, the present invention provides a novel OLED display panel and display device to solve the abovementioned technical problems.

### SUMMARY OF INVENTION

To solve the abovementioned technical problems, the solution provided by the present disclosure is shown as follows:

The present disclosure provides a flexible substrate material which includes a polyimide substrate and a carbon nanotube reinforcement. The carbon nanotube reinforcement is dispersed in the polyimide substrate and linked with the polyimide substrate by chemical bonds.

In one embodiment, the carbon nanotube reinforcement includes a one-dimensional carbon nanotube reinforcement phase and a two-dimensional carbon nanotube reinforcement phase.

In one embodiment, the one-dimensional carbon nanotube reinforcement phase and the two-dimensional carbon nanotube reinforcement phase of the carbon nanotube reinforcement are linked with each other by chemical bonds.

In one embodiment, the chemical bonds are amide bonds and/or conjugated bonds and/or hydrogen bonds.

In one embodiment, the one-dimensional carbon nanotube reinforcement phase is a carbon nanotube or a carbon oxide nanotube.

In one embodiment, the carbon nanotube and the carbon oxide nanotube include a single wall structure or a multiple wall structure.

In one embodiment, the two-dimensional carbon nanotube reinforcement phase is graphene or graphene oxide.

In one embodiment, the graphene and the graphene oxide include a single wall structure or a multiple wall structure.

The present disclosure further provides a method of manufacturing a flexible display panel substrate, including steps of:

reacting a one-dimensional carbon nanotube reinforcement phase with a two-dimensional carbon nanotube reinforcement phase to obtain a three-dimensional carbon nanotube reinforcement phase;

reacting the three-dimensional carbon nanotube reinforcement phase with 4,4′-diaminodiphenyl ether and pyromellitic dianhydride to obtain a flexible substrate material solution;

coating the flexible substrate material solution on a glass substrate; and

drying the glass substrate to obtain a flexible display panel substrate attached on the glass substrate.

In one embodiment, the step of reacting the one-dimensional carbon nanotube reinforcement phase with the two-dimensional carbon nanotube reinforcement phase to obtain the three-dimensional carbon nanotube reinforcement phase includes steps of:

dispersing the one-dimensional carbon nanotube reinforcement phase and the two-dimensional carbon nanotube reinforcement phase in a dimethylformamide solution to obtain a first mixture;

adding p-phenylenediamine, N-hydroxy succinimide and carbodiimide into the first mixture, allowing a cross-linking reaction to be occurred between the one-dimensional carbon nanotube reinforcement phase and the two-dimensional carbon nanotube reinforcement phase to obtain a second mixture; and filtering the second mixture to obtain the three-dimensional carbon nanotube reinforcement phase.

In one embodiment, a drying process is needed after obtaining the three-dimensional carbon nanotube reinforcement phase by filtering the second mixture.

In one embodiment, the step of reacting the three-dimensional carbon nanotube reinforcement phase with 4,4′-diaminodiphenyl ether and pyromellitic dianhydride to obtain the flexible substrate material solution includes steps of:

dispersing the three-dimensional carbon nanotube reinforcement phase in the N-methylpyrrolidone solution to obtain a third mixture;

adding 4,4′-diaminodiphenyl ether and pyromellitic dianhydride into the third mixture and stirring for mixing to obtain a fourth mixture; and

adding N-hydroxy succinimide and carbodiimide into the fourth mixture and stirring to obtain the flexible substrate material solution.

In one embodiment, a method of coating the flexible substrate material solution on the glass substrate is spin coating.

In one embodiment, a method of drying the glass substrate is placing the glass substrate in an environment of between 100° C. to 300° C. for 1 to 2 hours.

In one embodiment, the one-dimensional carbon nanotube reinforcement phase is carbon nanotube or carbon oxide nanotube, and the two-dimensional carbon nanotube reinforcement phase is graphene or graphene oxide.

In one embodiment, the three-dimensional carbon nanotube reinforcement phase is formed by linking the one-dimensional carbon nanotube reinforcement phase with the two-dimensional carbon nanotube reinforcement phase through chemical bonds.

In one embodiment, the chemical bonds are amide bonds and/or conjugated bonds and/or hydrogen bonds.

In one embodiment, the three-dimensional carbon nanotube reinforcement phase is formed by linking the one-dimensional carbon nanotube reinforcement phase with the two-dimensional carbon nanotube reinforcement phase through physical connection.

In one embodiment, the method further includes a step of detaching the flexible display panel from the glass substrate.

The present disclosure further provides a flexible display panel, which includes a flexible display panel substrate manufactured by the abovementioned method of manufacturing the flexible display panel substrate.

The beneficial effects of the present disclosure are that the flexible substrate material provided by the present disclosure includes a polyimide substrate and a carbon nanotube reinforcement mixed in the polyimide substrate, comparing to the pure polyimide material. The flexible substrate material provided by the present disclosure has better abilities of curl deformation resistance and crack resistance. The method of manufacturing a flexible display substrate provided by the present disclosure provides the flexible display panel substrate with better abilities of curl deformation resistance and crack resistance by introducing the carbon nanotube reinforcement phase into the synthesis process of the phase of the polyimide substrate.

### BRIEF DESCRIPTION OF DRAWINGS

In order to more clearly illustrate the technical solutions in the embodiments of the present invention, the drawings used in the description of the embodiments will be briefly described below. It is obvious that the drawings in the following description are only some embodiments of the present invention. Other drawings can also be obtained from those skilled persons in the art based on these drawings without paying any creative effort.

FIG. 1 is a schematic view of the structure of the flexible substrate material according to one embodiment of the present invention.

FIG. 2 is a schematic view of the density of a flowchart of a method of manufacturing a flexible display panel substrate according to one embodiment of the present invention.

FIG. 3 is a specific flowchart of step S1 of the method of manufacturing a flexible display panel substrate as shown in FIG. 2.

FIG. 4 is a specific flowchart of step S2 of the method of manufacturing a flexible display panel substrate as shown in FIG. 2.

### DETAILED DESCRIPTION OF PREFERRED EMBODIMENTS

The description of each of the following embodiments is provided with reference to the appending drawings to exemplify the specific embodiment that may be implemented. The directional terms, such as “upper,” “lower,” “front,” “back,” “left,” “right,” “inside,” “outside,” and “lateral side” are based on the orientation or positional relationship shown in the drawings, and the terms are merely for convenience of description of the present invention, and thus they are not to be construed as limiting. In the drawings, elements with similar structure are denoted by the same reference symbols.

One embodiment of the present disclosure provides a flexible substrate material used for manufacturing a flexible display panel substrate. The flexible substrate material includes a polyimide substrate phase and a nanotube reinforcement phase mixed in the polyimide substrate phase. The flexible substrate material provided by the embodiment of the present disclosure has better abilities of curl deformation resistance and crack resistance as comparing to simple polyimide material. Another embodiment of the present disclosure further provides a method of manufacturing the flexible display panel substrate by use of the flexible substrate material, and a flexible display panel containing the flexible display panel substrate manufactured by the method.

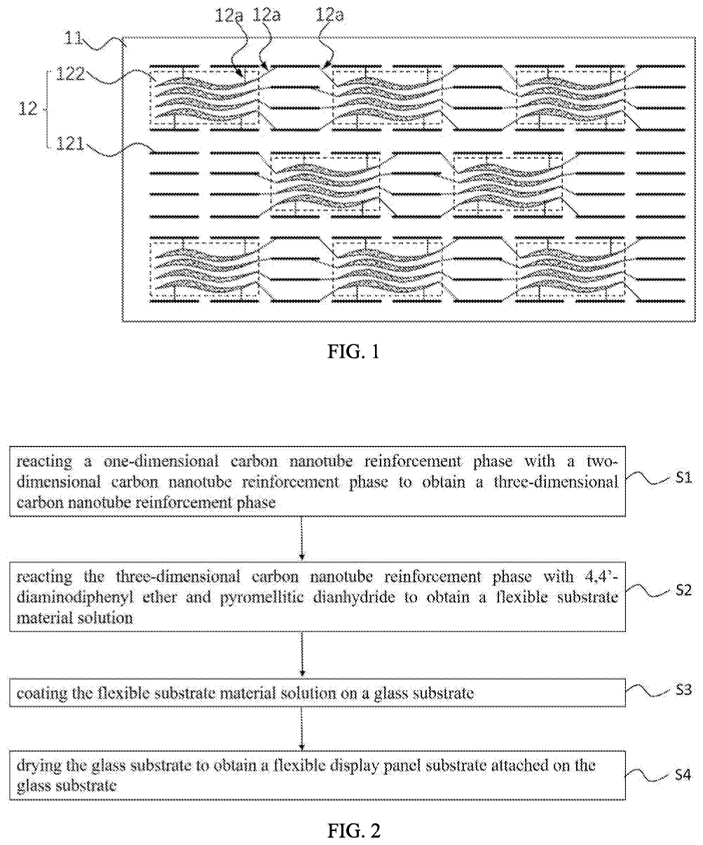

Referring to FIG. 1, it is a schematic structural view of a flexible substrate material provided by one embodiment of the present disclosure. The flexible substrate material includes a polyimide substrate 11 and a carbon nanotube reinforcement 12. The carbon nanotube reinforcement 12 is dispersed in the polyimide substrate 11, and is linked with the polyimide substrate 11 by chemical bonds, thereby reinforcing the interface strength between the polyimide substrate 11 and the carbon nanotube reinforcement 12. The flexible substrate material is a composite structure. The polyimide substrate 11 is used as a substrate phase, and the carbon nanotube reinforcement 12 is used as a reinforcing phase. Thus, the flexible substrate material provided by the present embodiment has advantages in mechanical properties, which presents excellent abilities of curl deformation resistance and crack resistance as comparing to simple polyimide material.

The structure of the polyimide substrate 11 is shown as follows:

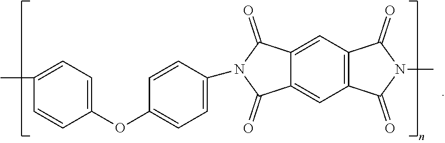

Optionally, the carbon nanotube reinforcement 12 may be a one-dimensional linear carbon nanotube reinforcement phase, a two-dimensional carbon nanotube reinforcement phase or three-dimensional carbon nanotube reinforcement phase. For example, the carbon nanotube reinforcement 12 may be a carbon nanotube, a carbon oxide nanotube, graphene, graphene oxide, or a combination of the graphene and carbon nanotube. In one embodiment, the carbon nanotube and carbon oxide nanotube may include a single wall structure or a multiple wall structure. The graphene and graphene oxide may include a single wall structure or a multiple wall structure.

According to one embodiment of the present disclosure, in the flexible substrate material, the carbon nanotube reinforcement 12 includes a one-dimensional carbon nanotube reinforcement phase 121 and a two-dimensional carbon nanotube reinforcement phase 122. The one-dimensional carbon nanotube reinforcement phase 121 has a linear structure, and the two-dimensional carbon nanotube reinforcement phase 122 has a planar structure. The one-dimensional carbon nanotube reinforcement phase 121 and the two-dimensional carbon nanotube reinforcement phase 122 distributed in the polyimide substrate 11 is regular or irregular.

Optionally, the one-dimensional carbon nanotube reinforcement phase 121 is linked with the two-dimensional carbon nanotube reinforcement phase 122 by chemical bonds 12a, allowing the one-dimensional carbon nanotube reinforcement phase 121 and the two-dimensional carbon nanotube reinforcement phase 122 to be formed in a whole structure, increasing the reinforcement effect to the polyimide substrate 11.

Optionally, the chemical bond 12a may be amide bonds and/or conjugated bonds and/or hydrogen bonds. In one embodiment, the amide bonds are the chemical bonds with the —CO—NH— structure. The conjugated bonds are conjugated bonds formed by orbital electron hybridization of carbon atoms. The hydrogen bonds are the bonding force between adjacent atoms formed by hydrogen atoms.

Optionally, the one-dimensional carbon nanotube reinforcement phase 121 is a carbon nanotube or a carbon oxide nanotube. The two-dimensional carbon nanotube reinforcement phase 122 is graphene or graphene oxide. In one embodiment, the carbon nanotube is a nanoscale tubular structure arranged by carbon atoms. The structure of the carbon oxide nanotube is the structure of the carbon nanotube with oxygen atoms. The graphene is a nanoscale sheet structure arranged by carbon atoms. The graphene oxide is the structure of the graphene with oxygen atoms. The carbon nanotube and the carbon oxide nanotube may include a single wall structure or a multiple wall structure. The graphene and the graphene oxide may include a single wall structure or a multiple wall structure.

It should be understood that the flexible substrate material provided by one embodiment of the present disclosure includes the polyimide substrate 11 and the carbon nanotube reinforcement 12 dispersed in the polyimide substrate 11. Comparing to the pure polyimide material, the material with composite structure has more excellent ability of curl deformation resistance. Moreover, the carbon nanotube reinforcement 12 may inhibit the crack propagation, extend the crack propagation path and increase the difficulty of crack propagation, thereby providing the material with excellent ability of crack resistance.

Referring to FIG. 2, it is the flowchart of the method of manufacturing the flexible display panel substrate provided by one embodiment of the present disclosure. The method of manufacturing the flexible display panel substrate comprises the following steps:

Step S1. A one-dimensional carbon nanotube reinforcement phase is reacted with a two-dimensional carbon nanotube reinforcement phase to obtain a three-dimensional carbon nanotube reinforcement phase.

Specifically, the one-dimensional carbon nanotube reinforcement phase has a linear structure, and the two-dimensional carbon nanotube reinforcement phase has a sheet structure. For example, the one-dimensional carbon nanotube reinforcement phase may be a carbon nanotube or a carbon oxide nanotube with a linear form. The two-dimensional carbon nanotube reinforcement phase may be graphene or graphene oxide with a sheet form. Moreover, the carbon nanotube and carbon oxide nanotube may include a single wall structure or a multiple wall structure. The method for preparing the one-dimensional carbon nanotube reinforcement phase and the two-dimensional carbon nanotube reinforcement phase may be a conventional method. For example, the one-dimensional carbon nanotube reinforcement phase may be prepared by chemical vapor deposition method, and the two-dimensional carbon nanotube reinforcement phase may be prepared by oxidation-reduction method. The one-dimensional carbon nanotube reinforcement phase and the two-dimensional carbon nanotube reinforcement phase may be read-made materials.

The three-dimensional carbon nanotube reinforcement phase may be a three-dimensional reinforcement structure formed by linking the one-dimensional carbon nanotube reinforcement phase with the two-dimensional carbon nanotube reinforcement phase through physical connection and/or chemical bonds.

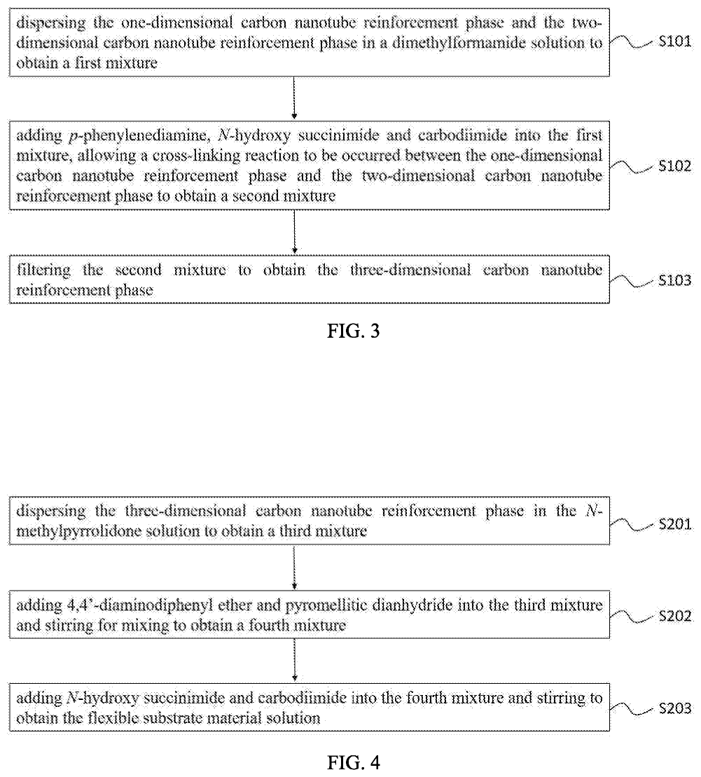

Referring to FIG. 3, the step S1 specifically comprises the following steps:

Step S101. The one-dimensional carbon nanotube reinforcement phase and the two-dimensional carbon nanotube reinforcement phase are dispersed in a dimethylformamide solution to obtain a first mixture. In one embodiment, the dimethylformamide solution may be used as a dispersant for mixing the one-dimensional carbon nanotube reinforcement phase and the two-dimensional carbon nanotube reinforcement phase well.

Step S201. p-Phenylenediamine, N-hydroxy succinimide and carbodiimide are added into the first mixture, allowing a cross-linking reaction to be occurred between the one-dimensional carbon nanotube reinforcement phase and the two-dimensional carbon nanotube reinforcement phase to obtain a second mixture.

Specifically, the cross-linking reaction occurred between the one-dimensional carbon nanotube reinforcement phase and the two-dimensional carbon nanotube reinforcement phase allows amide bonds to be created between the one-dimensional carbon nanotube reinforcement phase and the two-dimensional carbon nanotube reinforcement phase, thereby forming in a whole structure, i.e. forming the three-dimensional carbon nanotube reinforcement phase. Moreover, during the cross-linking reaction, the one-dimensional carbon nanotube reinforcement phase may link with the two-dimensional carbon nanotube reinforcement phase by conjugated bonds and hydrogen bonds, thereby further enhancing the linkage between the one-dimensional carbon nanotube reinforcement phase and the two-dimensional carbon nanotube reinforcement phase.

In one embodiment, the amide bonds are the chemical bonds with the —CO—NH— structure. The conjugated bonds are conjugated bonds formed by orbital electron hybridization of carbon atoms. The hydrogen bonds are the bonding force between adjacent atoms formed by hydrogen atoms.

Step 103. The second mixture is filtered to obtain the three-dimensional carbon nanotube reinforcement phase.

Specifically, the filters are dried after filtering the second mixture to obtain the three-dimensional carbon nanotube reinforcement phase.

Step S2. The three-dimensional carbon nanotube reinforcement phase is reacted with 4,4′-diaminodiphenyl ether and pyromellitic dianhydride to obtain a flexible substrate material solution.

In one embodiment, the structure of the 4,4′-diaminodiphenyl ether is shown as follows:

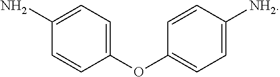 [SMILES: Nc1ccc(Oc2ccc(N)cc2)cc1]

The structure of the pyromellitic dianhydride is shown as follows:

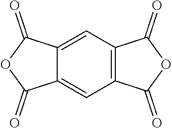 [SMILES: O=c1oc(=O)c2cc3c(=O)oc(=O)c3cc12]

Referring to FIG. 4, the step S2 specifically includes the following steps:

Step S201. The three-dimensional carbon nanotube reinforcement phase is dispersed in the N-methylpyrrolidone solution to obtain a third mixture.

In one embodiment, the N-methylpyrrolidone solution is used as a dispersant. Operations such as stirring or shaking may be performed during the dispersion to accelerate dispersion and disperse evenly. It should be noted that an appropriate amount of the three-dimensional carbon nanotube reinforcement phase may be selected according to needs in actual manufacturing process. It should be understood that higher contents of the three-dimensional carbon nanotube reinforcement phase provide the flexible display panel substrate finally manufactured with better abilities of curl deformation resistance and crack resistance. However, in order to ensure that the finally manufactured flexible display panel substrate has sufficient flexibility, the amount of the three-dimensional carbon nanotube reinforcement phase used is generally limited. The amount of the three-dimensional carbon nanotube reinforcement phase used in the present disclosure is not limited, and the amount of the three-dimensional reinforcement phase is controlled according to actual needs.

Step S202. 4,4′-Diaminodiphenyl ether and pyromellitic dianhydride are added into the third mixture and stirred for mixing to obtain a fourth mixture. Specifically, stirring or shaking may be performed while adding the 4,4′-diaminodiphenyl ether and the pyromellitic dianhydride into the third mixture to ensure the 4,4′-diaminodiphenyl ether, the pyromellitic dianhydride, and the three-dimensional reinforcement phase being mixed evenly.

Step S203. N-Hydroxy succinimide and carbodiimide are added into the fourth mixture and stirred to obtain the flexible substrate material solution.

In one embodiment, the N-hydroxy succinimide and the carbodiimide are used as accelerants in the reaction for enhancing the condensation reaction to be occurred between the N-Hydroxy succinimide and the carbodiimide.

Specifically, polyimide is formed by a two-step reaction between the N-Hydroxy succinimide and the carbodiimide.

In one embodiment, the first step is a condensation reaction to produce polyacrylic acid mesophase by the following reaction formula:

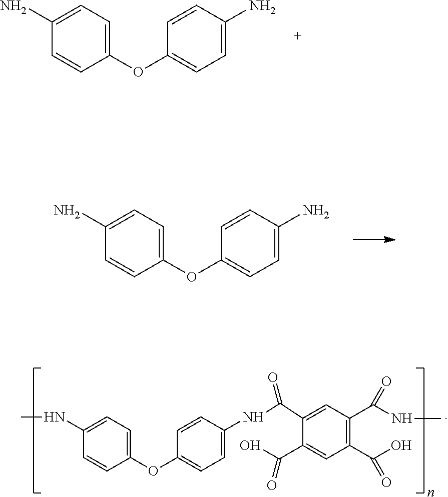

The second step is an imination reaction to produce polyimide by the following reaction formula:

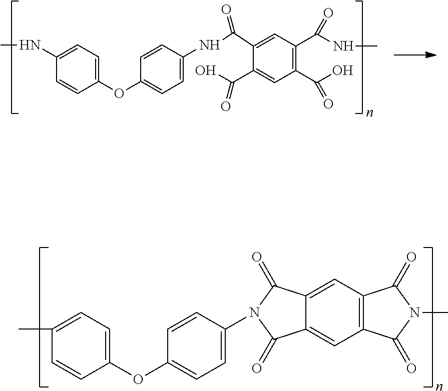

It should be noted that while the 4,4′-diaminodiphenyl ether reacting with the pyromellitic dianhydride to form polyimine, the three-dimensional carbon nanotube reinforcement phase is mixed in the produced polyimide substrate, and linked with the polyimide substrate by chemical bonds, thereby forming a network structure constituted by the polyimide substrate and carbon nanotube reinforcement. The network structure has good abilities of curl deformation resistance and crack resistance.

Step S3. The flexible substrate material solution is coated on a glass substrate.

Specifically, a method of coating the flexible substrate material solution on the glass substrate is spin coating.

Step S4. The glass substrate is dried to obtain a flexible display panel substrate attached on the glass substrate.

Specifically, a method of drying the glass substrate is placing the glass substrate in an environment of between 100° C. to 300° C. for 1 to 2 hours. The solvent of the flexible substrate material solution coated on glass substrate may be volatilized by the drying process. The flexible substrate material may condense into a film on the glass substrate, forming the flexible display panel substrate. It should be noted that the thickness of the flexible display panel substrate may be controlled by the quantity of the flexible substrate material solution coated on glass substrate. Different thicknesses of the flexible display panel substrate may be manufactured during manufacturing according to actual needs.

It is noted that the glass substrate is used for supporting the flexible display panel substrate. To prevent the flexible substrate from deforming and affect the quality of products, the glass substrate may be remained during manufacturing the display panel due to the flexibility of the flexible display panel substrate. The flexible display panel is detached from the glass substrate in the end of manufacturing process.

The method of manufacturing the flexible display panel substrate provided by the present disclosure allows the flexible display panel substrate finally produced to have the abilities of curl deformation resistance and crack resistance by introducing the carbon nanotube reinforcement phase into the synthesis process of the phase of the polyimide substrate.

One embodiment of the present disclosure further provides a flexible display panel. The flexible display panel comprises the flexible display panel substrate. The flexible display panel substrate is manufactured by the flexible substrate material provided by the embodiment of the present disclosure or by the method of manufacturing the flexible display panel substrate provided by the present disclosure. Due to the good abilities of curl deformation resistance and crack resistance of the flexible display panel substrate, the flexible display panel substrate may not be deformed by curling or cracking due to heating or force effects during the process of detaching the flexible display panel from the glass substrate, thereby increasing the quality of the flexible display panel.

In the above, the present disclosure has been described in the above preferred embodiments, but the preferred embodiments are not intended to limit the scope of the invention, and a person skilled in the art may make various modifications without departing from the spirit and scope of the application. The scope of the present application is determined by claims.

What is claimed is:

1. A flexible substrate material, comprising:
a polyimide substrate; and
a carbon nanotube reinforcement, wherein the carbon nanotube reinforcement is dispersed in the polyimide substrate and linked with the polyimide substrate by chemical bonds.

2. The flexible substrate material according to claim 1, wherein the carbon nanotube reinforcement comprises a one-dimensional carbon nanotube reinforcement phase and a two-dimensional carbon nanotube reinforcement phase.

3. The flexible substrate material according to claim 2, wherein the one-dimensional carbon nanotube reinforcement phase and the two-dimensional carbon nanotube reinforcement phase of the carbon nanotube reinforcement are linked with each other by chemical bonds.

4. The flexible substrate material according to claim 3, wherein the chemical bonds are amide bonds and/or conjugated bonds and/or hydrogen bonds.

5. The flexible substrate material according to claim 2, wherein the one-dimensional carbon nanotube reinforcement phase is a carbon nanotube or a carbon oxide nanotube.

6. The flexible substrate material according to claim 5, wherein the carbon nanotube and the carbon oxide nanotube comprise a single wall structure or a multiple wall structure.

7. The flexible substrate material according to claim 2, wherein the two-dimensional carbon nanotube reinforcement phase is graphene or graphene oxide.

8. The flexible substrate material according to claim 7, wherein the graphene and the graphene oxide comprise a single wall structure or a multiple wall structure.

9. A method of manufacturing a flexible display panel substrate, comprising steps of:
reacting a one-dimensional carbon nanotube reinforcement phase with a two-dimensional carbon nanotube reinforcement phase to obtain a three-dimensional carbon nanotube reinforcement phase;
reacting the three-dimensional carbon nanotube reinforcement phase with 4,4′-diaminodiphenyl ether and pyromellitic dianhydride to obtain a flexible substrate material solution;
coating the flexible substrate material solution on a glass substrate; and
drying the glass substrate to obtain a flexible display panel substrate attached on the glass substrate.

10. The method of manufacturing the flexible display panel substrate according to claim 9, wherein step of reacting the one-dimensional carbon nanotube reinforcement phase with the two-dimensional carbon nanotube reinforcement phase to obtain the three-dimensional carbon nanotube reinforcement phase comprises steps of:
dispersing the one-dimensional carbon nanotube reinforcement phase and the two-dimensional carbon nanotube reinforcement phase in a dimethylformamide solution to obtain a first mixture;
adding p-phenylenediamine, N-hydroxy succinimide and carbodiimide into the first mixture, allowing a cross-linking reaction to be occurred between the one-dimensional carbon nanotube reinforcement phase and the two-dimensional carbon nanotube reinforcement phase to obtain a second mixture; and
filtering the second mixture to obtain the three-dimensional carbon nanotube reinforcement phase.

11. The method of manufacturing the flexible display panel substrate according to claim 10, wherein a drying process is needed after obtaining the three-dimensional carbon nanotube reinforcement phase by filtering the second mixture.

12. The method of manufacturing the flexible display panel substrate according to claim 9, wherein step of reacting the three-dimensional carbon nanotube reinforcement phase with 4,4′-diaminodiphenyl ether and pyromellitic dianhydride to obtain the flexible substrate material solution comprises steps of:
dispersing the three-dimensional carbon nanotube reinforcement phase in the N-methylpyrrolidone solution to obtain a third mixture;
adding 4,4′-diaminodiphenyl ether and pyromellitic dianhydride into the third mixture and stirring for mixing to obtain a fourth mixture; and
adding N-hydroxy succinimide and carbodiimide into the fourth mixture and stirring to obtain the flexible substrate material solution.

13. The method of manufacturing the flexible display panel substrate according to claim 9, wherein a method of coating the flexible substrate material solution on the glass substrate is spin coating.

14. The method of manufacturing the flexible display panel substrate according to claim 9, wherein a method of drying the glass substrate is placing the glass substrate in an environment of between 100° C. to 300° C. for 1 to 2 hours.

15. The method of manufacturing the flexible display panel substrate according to claim 9, wherein the one-dimensional carbon nanotube reinforcement phase is carbon nanotube or carbon oxide nanotube, and the two-dimensional carbon nanotube reinforcement phase is graphene or graphene oxide.

16. The method of manufacturing the flexible display panel substrate according to claim 9, wherein the three-dimensional carbon nanotube reinforcement phase is formed by linking the one-dimensional carbon nanotube reinforcement phase with the two-dimensional carbon nanotube reinforcement phase through chemical bonds.

17. The method of manufacturing the flexible display panel substrate according to claim 16, wherein the chemical bonds are amide bonds and/or conjugated bonds and/or hydrogen bonds.

18. The method of manufacturing the flexible display panel substrate according to claim 9, wherein the three-dimensional carbon nanotube reinforcement phase is formed by linking the one-dimensional carbon nanotube reinforcement phase with the two-dimensional carbon nanotube reinforcement phase through physical connection.

19. The method of manufacturing a flexible display panel substrate according to claim 9, wherein the method further comprises a step of detaching the flexible display panel from the glass substrate.

20. A flexible display panel, comprising a flexible display panel substrate manufactured by the method of manufacturing the flexible display panel substrate as claimed in claim 9.
